(19) United States
(12) Patent Application Publication
(10) Pub. No.: US 2010/0283046 A1
(43) Pub. Date: Nov. 11, 2010

(54) ORGANIC ELECTROLUMINESCENT ELEMENT

(76) Inventor: Hideki Uchida, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/811,062

(22) PCT Filed: Aug. 28, 2008
(86) PCT No.: PCT/JP2008/065416

§ 371 Date: Jun. 28, 2010

(30) Foreign Application Priority Data
Dec. 28, 2007 (JP) 2007-340310

(51) Int. Cl. H01L 51/54

(52) U.S. Cl. 257/40; 257/E51.027

(57) ABSTRACT

The present invention provides an organic electroluminescent element having excellent electron injection properties and high resistance to external environmental factors, and providing buffer effects in transparent electrode formation. The present invention is an organic electroluminescent element having an anode, a cathode, and a light-emitting layer sandwiched between the anode and the cathode, the organic electroluminescent element comprising a nanoparticle layer containing metal oxide nanoparticles, between the light-emitting layer and the cathode.

### TECHNICAL FIELD

The present invention relates to an organic electroluminescent element. More specifically, the present invention relates to an organic electroluminescent element suitable as an organic electroluminescent element produced by a wet process.

### BACKGROUND ART

An organic electroluminescent element (hereinafter also referred to as an “organic EL element”) is generally an all-solid-state light-emitting element which has a pair of electrodes of an anode and a cathode, and a light-emitting layer sandwiched by the pair of electrodes. Being highly visible and resistant to shocks, an organic EL element is expected to be applied in broad fields such as displays, lightings, and the like.

The production process of an organic EL element is roughly divided, based on the film forming process, into a dry process employing a method such as deposition and a wet process employing a method such as coating. The wet process allows cost reduction in the production process and an increase in the area of a panel having an organic EL element.

Here, description is given for the structure of conventional organic EL elements (coating-type organic EL elements) in which a light-emitting layer is formed by coating. FIG. 11 is a cross-sectional view schematically illustrating a conventional coating-type organic EL element.

As illustrated in FIG. 11, a conventional coating-type organic EL element has a structure where an anode 2, a hole transport layer 3, a light-emitting layer 4, and a cathode 6, made of a stack of an active metal and an inert metal, are stacked on a substrate 1 in the stated order.

Such a conventional coating-type organic EL element is usually produced through the following processes. First, a solution prepared by dissolving a hole transport material in a solvent is applied on the anode 2. Next, the solvent is removed to leave the hole transport layer 3, and then the hole transport layer 3 is coated with a solution prepared by dissolving a light-emitting material in a solvent that does not dissolve the hole transport material. Thereafter, the solvent is removed to leave the light-emitting layer 4, and then an active metal such as Ca and Ba and an inert metal such as Al and Ag serving as a sealing metal are deposited on the light-emitting layer 4 in the stated order so that the cathode 6 is formed.

An organic EL element serving as a display, in the development thereof, is sometimes used in combination with an active element. In this case, if the light is emitted toward the substrate on which an active element is provided, i.e., if the bottom emission structure is employed, the active element can be a factor of decreasing the aperture ratio in light emission. Accordingly, investigations have been made on organic EL elements having the top emission structure in which the light is emitted toward the reverse direction of the substrate on which an active element is provided.

Meanwhile, with respect to optical devices, Patent Document 1, for example, discloses an optical device having a layer made of an organic material in which light transmissive nanoparticles are dispersed in a substantially uniform manner.

### [Patent Document 1]

Japanese Kokai Publication No. 2002-520683

### DISCLOSURE OF INVENTION

However, stacking an electron transport material on the light-emitting layer 4 by coating has been difficult in production of conventional coating-type organic EL elements. In order to improve light-emitting efficiency and life characteristics of an organic EL element, electrons and holes need to be injected into a light-emitting layer at high efficiency in a balanced manner. This has been difficult in conventional coating-type organic EL elements, and improvement in the characteristics has been greatly dependent on the characteristics of the light-emitting material.

One of the reasons for the difficulty in stacking an electron transport material on the light-emitting layer 4 by coating is that there are limited options for the solvent. That is, if an electron transport material soluble in an organic solvent is applied on a light-emitting material soluble in an organic solvent, those materials will be mixed and an uneven film will be formed. Further, if a water-soluble electron transport material is applied, the light-emitting layer will be deteriorated due to the moisture. Furthermore, few coating-type electron transport materials exist today.

In contrast, any material can be stacked by deposition in which an organic layer is mainly made of low-molecular materials. For this reason, element characteristics can be improved by depositing an electron transport material on a light-emitting layer and improving characteristics of electron injection into the light-emitting layer. Particularly, inserting an electron injection layer having a LUMO level higher than that of the light-emitting layer makes it possible to increase injection efficiency.

Although attempts have been made to deposit a low-molecular electron injection and/or transport layer (electron injection transport layer) on a polymer light-emitting layer usually formed by coating, injection does not succeed in many cases. This is apparently because charge injection does not necessarily depend on the band gap between layer when a coating-type light-emitting material, particularly a polymer light-emitting material is used.

Even if there is an about 0.7 eV band gap between a hole transport material and a coating-type light-emitting material, charge injection is achieved ohmically in this interface, according to the following references: “D. Poplayskyy, J. Nelson, D. D. C. Bradley, “Ohmic hole injection in poly(9,9-dioctylfluorene) polymer light-emitting diodes”, Applied Physics Letters, the U.S., American Institute of Physics, Jul. 28, 2003, Volume 83, Issue 4, pp. 707-709” and “Hideki Uchida, Kenzo Mishima, Mitsuhiro Kouden, “Polymer organic EL mechanism analysis II by using single carrier device—characteristic voltage change of HOD”, The 66th Autumn Meeting of Japan Society of Applied Physics, proceedings, Japan. Society of Applied Physics, Sep. 5, 2005, Vol. 3, p. 1153”. These papers teach that traps formed in an interface and interaction between faces greatly affect the electrical conduction, that is, adjustment of band gaps does not lead to efficient injection if the affinity between the materials is low. Apparently, many of coating-type light-emitting materials, particularly polymer light-emitting materials have low affinity with low-molecular electron transport materials, and thus electron injection properties cannot be improved.

As above, stacking an electron injection transport layer on a coating-type light-emitting material, particularly a polymer light-emitting material, is difficult. Thus, in a conventional coating-type organic EL element, electron injection is achieved by the cathode 6 and materials such as Ca and Ba are applied in order to achieve efficient electron injection. Since those electrode materials have a low work function and high affinity with polymer light-emitting materials in the interface, electron injection can be achieved efficiently.

However, those electrode materials have very high activity. That is, those electrode materials are oxidized easily by a small amount of moisture or oxygen penetrating from the outside. As a result, charge injection may be inhibited and the element characteristics may be deteriorated. Further, migration of those electrode materials may cause entry of the cathode into the light-emitting layer, which may form quenching sites and decrease luminance.

The general element structure in the top emission structure is AL/ITO (or IZO)/hole transport layer/light-emitting layer/transparent cathode. The transparent cathode here is a thin film of a cathode used in the bottom emission structure, i.e., a super-thin film metal cathode, and this provides transparency to the cathode. However, such a super-thin film metal cathode may not be able to secure a conductivity sufficient for a display. For this reason, the structure on the cathode side in the top emission structure may be a stacked structure of a light-emitting layer/ITO, or the like. In this case, if the ITO film is formed on the light-emitting layer by sputtering, the light-emitting layer may be deteriorated by secondary electrons emitted during the sputtering or the like. Therefore, development of an electron transport material is desired which functions also as a buffer layer for preventing adverse effects on the light-emitting layer.

As above, an electron transport material is desired which can be formed on a light-emitting layer, particularly on a coating-type light-emitting layer. Such an electron transport material is desired to have the following functions (1) to (3):

(1) an electron injection function for a light-emitting material;

(2) resistance to external environmental factors; and

(3) a buffer function for transparent electrode formation.

The present invention was made in view of the above-mentioned state of the art. The present invention aims to provide an organic electroluminescent element having excellent electron injection properties and high resistance to external environmental factors, and providing buffer effects in transparent electrode formation.

The present inventor made various investigations on organic electroluminescent elements which have excellent electron injection properties, and high resistance to external environmental factors, and provide buffer effects in transparent electrode formation. As a result, the inventor noted a technique of providing an electron injection layer between a light-emitting layer and a cathode. The inventor found that a nanoparticle layer containing metal oxide nanoparticles can provide the above functions (1) to (3), and that an organic electroluminescent element, by having such a nanoparticle layer between a light-emitting layer and a cathode, can lead to an admirable solution to the above problem, whereby the present invention has been completed.

That is, the present invention is an organic electroluminescent element (organic EL element) having an anode, a cathode, and a light-emitting layer sandwiched between the anode and the cathode, the organic electroluminescent element comprising: a nanoparticle layer containing metal oxide nanoparticles, between the light-emitting layer and the cathode. This can achieve an organic EL element having excellent electron injection properties and high resistance to external environmental factors, and providing buffer effects in transparent electrode formation.

The configuration of the organic EL element of the present invention is not specifically limited as long as the element includes the above components, and may or may not include other components. The present invention and preferable embodiments of the organic EL element of the present invention are described in detail below. Note that the various embodiments below may be appropriately combined.

First, the electron injection properties of the organic EL element of the present invention are described.

The present inventor found that metal oxide nanoparticles have excellent conductivity, and that forming a nanoparticle layer containing metal oxide nanoparticles, between a light-emitting layer and a cathode, allows efficient electron injection into the light-emitting layer. Particularly, applying metal oxide nanoparticles having electron injection properties allows very easy electron injection into the light-emitting layer.

The following reasons are considered to explain the conductivity and charge injection properties of metal oxide nanoparticles.

### (Reason 1)

Metal oxide nanoparticles form charge transfer complexes in an interface with an electrode or with an organic layer (layer containing organic compounds) forming the interface. More specifically, charge transfer complexes (metal complexes) are formed between the oxide on the metal oxide nanoparticles and the electrode, or between the metal on the metal oxide nanoparticles and organic components constituting the organic layer. For this reason, apparently, charge is carried by the charge transfer complexes into the light-emitting layer and thus electron injection is achieved even if a band gap exists between the electrode and the metal oxide nanoparticles or between the metal oxide nanoparticles and the organic layer.

### (Reason 2)

A metal oxide, although being a dielectric itself, may sometimes not be in a completely oxidized state or a part of the material may sometimes not be completely oxidized in the nanoparticulation process. The existence of such an imperfect oxide in terms of electronic materials produces superfluous electrons and holes. That is, a layer formed by forming such metal oxide nanoparticles into a film turns out to have many internal charges. Applying an electric field to this layer moves the internal charges to a counter electrode, which gives current. The current is proportional to the internal charges and the charge mobility. Hence, a larger component ratio of those insufficient oxides, i.e., imperfect oxides allows more charges to flow through a layer containing metal oxide nanoparticles. The deficiency in metal oxides usually occurs in nanoparticle production. Therefore, different production methods for the same metal oxide can cause different deficiencies, that is, oxygen deficiency or metal deficiency. Accordingly, since the electron mobility and the hole mobility of the metal oxide change according to the production condition, a metal oxide material is preferably selected in accordance with the required characteristics.

For the above reasons, it appears that stacking metal oxide nanoparticles on the cathode side of the light-emitting layer leads to efficient electron injection into the light-emitting layer.

The metal oxide nanoparticles in the present invention have a function to perform electron injection and/or electron transportation. As mentioned above, the mechanism of the electron injection and/or electron transportation by the metal oxide nanoparticles in the present invention is considered to be different from the mechanism of the electron injection and/or electron transportation by layers such as so-called electron injection layer, electron transport layer, and electron injection transport layer which are used in a conventional organic EL element produced by a dry process. However, for convenience of explanation herein, there are descriptions such as “metal oxide nanoparticles have electron injection properties and/or electron transport properties”, “electron-injection/electron-transport metal oxide nanoparticles”, and the like.

The number of the light-emitting layers is not specifically limited as long as at least one light-emitting layer is provided.

Further, the number of the kinds of the metal oxide nanoparticles is not specifically limited as long as at least one kind of metal oxide nanoparticles is provided.

In the following, a preferable embodiment of achieving more efficient electron injection into the light-emitting layer is described.

As described in Reason 2, the metal oxide nanoparticles preferably include imperfect oxides (metal deficiency). Thus, after formation of a nanoparticle layer containing metal oxide nanoparticles, a sintering process accelerating crystallization of the metal oxide nanoparticles is preferably not performed so that the metal oxide nanoparticles have a deficiency. This leads to superfluous electrons and holes in the nanoparticle layer and thus provides internal charges to the nanoparticle layer.

As described in Reason 1, the metal oxide nanoparticles and the adjacent layer preferably form charge transfer complexes. Since the affinity of the light-emitting layer and the nanoparticle layer changes according to the light-emitting material, it is preferable to appropriately select the kind of metal oxide nanoparticles having high affinity with the light-emitting material.

The metal oxide nanoparticles preferably have an electron transport level higher than the electron transport level of the light-emitting layer. As described above, the existence of a band gap does not necessarily inhibit charge injection. However, if metal oxide nanoparticles have an electron transport level higher than the electron transport level of the light-emitting layer, electrons can be injected into the light-emitting layer without hindrance. Accordingly, more effective electron injection can be achieved.

Next, the external factor resistance of the organic EL element of the present invention is described.

The present inventor found that the metal oxide nanoparticles provide another effect; that is, the nanoparticles can effectively suppress a decrease in the element characteristics due to external environmental factors. Being a material stable in even the atmosphere unlike a conventional cathode containing an active metal such as Ca and Ba, metal oxide nanoparticles are not deteriorated by neither moisture nor oxygen and thus can extend the element life.

Usually, metal oxide nanoparticles each have a particle diameter of about 5 to 50 nm and do not migrate to the light-emitting layer. For this reason, a problem does not arise in which migrated metal oxide nanoparticles form quenching sites with the light-emitting layer and decrease the element characteristics.

In the following, a preferable embodiment of further increasing the resistance to external factors is described.

As described above, since charge injection properties are sufficiently secured by the nanoparticle layer, the organic EL element of the present invention does not need to contain an active metal such as calcium (Ca) and barium (Ba) as a cathode on the light-emitting layer to achieve efficient electron injection to the light-emitting layer. As a result, an inert, stable metal such as aluminum (Al) and silver (Ag) can be used as a cathode, and thus the element life can be further extended. As above, the cathode preferably contains an inert metal.

Next, description is given to the buffer effects on a transparent electrode of the organic EL element of the present invention having the top emission structure.

Another effect of metal oxide nanoparticles is the buffer effects in transparent electrode formation. The metal oxide itself is stable during the process of forming a transparent electrode. This can effectively suppress damage to the light-emitting layer which is caused in conventional formation of a transparent electrode on the light-emitting layer directly or via an super-thin film metal cathode.

Even with an super-thin film metal cathode, damage to the light-emitting layer can be decreased if the light-emitting layer is perfectly covered. However, since priority is actually given to transparency, the super-thin film metal cathode needs to have a very small thickness of about 3 to 5 nm. This leads to generation of regions without the metal cathode formed therein, i.e., generation of the sea island structure. Also, with such a small thickness of the metal cathode, even a region with the metal cathode formed therein cannot prevent damage to the light-emitting layer.

In contrast, a nanoparticle layer maintains electron injection properties even when having a somewhat large thickness, and also has light transparency since containing nanoparticles. Accordingly, depositing metal oxide nanoparticles on the light-emitting layer makes it possible to completely cover the light-emitting layer surface with a nanoparticle layer to protect the light-emitting layer from damage caused by transparent electrode formation, while the transparency can be maintained.

In the following, description is given to an embodiment which is preferable to efficiently achieve the buffer effects in transparent electrode formation.

A layer to be formed as the cathode is preferably formed by sputtering. That is, the cathode is preferably formed by sputtering. Sputtering enables formation of a dense cathode electrode having excellent electrode performance, evenness, and the like compared to conventional cathode formation by vapor deposition. Of course, the nanoparticle layer functions as a buffer layer in the present invention, which effectively prevents this process from deteriorating the light-emitting layer.

The transparent electrode is preferably formed as a cathode. That is, the cathode is preferably transparent. This makes it possible to produce an organic EL element having the top emission structure, a transparent organic EL element in which the whole element is transparent, or the like.

In the following, another preferable embodiment of the organic EL element of the present invention is described.

In the above, the effects of metal oxide nanoparticles have been described. The present inventor found that those effects can also be achieved by a layer containing metal oxide nanoparticles. That is, the nanoparticle layer may be made of the metal oxide nanoparticles, or may be made of a film containing the metal oxide nanoparticles.

A metal oxide nanoparticle usually has a modifying layer of about a few nm on the surface of the particle, and this structure increases dispersibility in a solvent and adhesion to a substrate. However, some kinds of metal oxide nanoparticle materials provide such a function at a very low level and have low self supporting properties. In such a case, the metal oxide nanoparticle material and a binder material can be combined to provide a material having high self supporting properties. Also in this case, a nanoparticle layer can be easily formed on the light-emitting layer. Here, too, adjusting the mixing ratio and the kind of binder according to the materials can sufficiently achieve effects of the above metal oxide nanoparticles.

An embodiment that is preferable to achieve the above effects more efficiently is described below.

As the material (binder) into which metal oxide nanoparticles are mixed, a polymer support is preferable. That is, the nanoparticle layer preferably contains the metal oxide nanoparticles and a polymer support. As above, the nanoparticle layer may be a nanoparticle-containing film that contains metal oxide nanoparticles and a polymer support. A polymer support, which is a polymer material, has excellent film formation properties and enables substantially uniform dispersion of a metal oxide nanoparticle mixture, thereby enabling easy formation of a stable film on the light-emitting layer.

Further, the number of the kinds of the polymer supports is not specifically limited as long as at least one kind of polymer support is provided.

As the material (binder) into which metal oxide nanoparticles are mixed, a material having electron transport properties is preferable. In this case, the binder (preferably binder resin) itself may have electron transport properties, or a material having electron transport properties may be mixed into the binder together with metal oxide nanoparticles. Examples of the material having electron transport properties, to be mixed into the binder together with metal oxide nanoparticles, include Alq3. Although having sufficient electron transport properties, the metal oxide nanoparticles may possibly not be able to effectively transport their electrons if the nanoparticles are small and the concentration of the nanoparticles dispersed uniformly in the binder is a low. Consequently, a material having electron transport properties is used as a material constituting a nanoparticle layer, as well as the metal oxide nanoparticles, so that the high electron transport properties of the metal oxide nanoparticles are more effectively extracted.

Further, when a metal oxide nanoparticle material is mixed into a binder, aggregated metal oxide nanoparticles are preferably mixed into the binder. That is, the nanoparticle layer preferably contains cluster aggregates of the metal oxide nanoparticles. As described above, the metal oxide nanoparticles may possibly not be able to effectively transport their electrons if the nanoparticles have a low concentration, are dispersed uniformly in the binder, and the amount thereof is small. In contrast, aggregates of metal oxide nanoparticles can effectively transport charges, thereby effectively activating the charge transport mechanism of the metal oxide nanoparticles.

The organic electroluminescent element preferably has a hole blocking layer between the light-emitting layer and the nanoparticle layer. Part of holes injected into the light-emitting layer from the anode side may possibly pass through the light-emitting layer, and leak into the cathode side serving as the counter electrode. This leakage current does not contribute to light emission, being a factor to decrease the efficiency of the element. The metal oxide nanoparticles having electron transport properties is usually in an insulating state to a hole, which means that the nanoparticles have a mechanism that blocks holes. Further stacking a layer (preferably organic layer) having a hole transport blocking function between the light-emitting layer and the nanoparticle layer prevents leakage of holes into the counter electrode, thereby increasing the light emission efficiency.

The light-emitting layer preferably contains metal oxide nanoparticles. Some light-emitting materials have low electron transport properties. Such materials may possibly deteriorate the IV characteristics and increase the driving voltage. Effectively flowing electrons in the light-emitting layer and thereby efficiently causing recombination of electrons and holes are preferable to increase the efficiency. In view of this, metal oxide nanoparticles having electron transport properties can be mixed also into the light-transmitting materials to increase the electron transport properties of the light-emitting layer so that the organic EL element of the present invention can achieve low voltage and high efficiency.

Further, the number of the kinds of the metal oxide nanoparticles to be contained in the light-emitting layer is not specifically limited as long as at least one kind of metal oxide nanoparticles is provided.

An embodiment that is preferable to achieve the above effects more efficiently is described below.

The metal oxide nanoparticles contained in the light-emitting layer preferably include the same kind of particles as the metal oxide nanoparticles contained in the nanoparticle layer. In this case, electrons are directly injected from the nanoparticle layer serving as an electron transport layer into the electron-transport metal oxide nanoparticles in the light-emitting layer, whereby more efficient electron injection is achieved. In view of this, the metal oxide nanoparticles contained in the light-emitting layer are more preferably of the same kind as the metal oxide nanoparticles contained in the nanoparticle layer.

The metal oxide nanoparticles contained in the light-emitting layer preferably have an electron transport level higher than the electron transport level of the light-emitting layer. If the light-emitting layer (light-emitting material) has a higher LUMO level than the electron transfer level of the metal oxide nanoparticles, electrons are mainly conducted. at the level of the metal oxide nanoparticles during movement of electrons in the light-emitting layer. In this case, recombination of electrons and holes hardly occurs in the light-emitting layer (light-transmitting material), and thus the light emission efficiency may possibly decrease. Even if recombination sites are generated within the light-emitting layer, transfer of energy to the level of the metal oxide nanoparticles may occur, that is, energy may be transferred to the level of metal oxide nanoparticles, which may lead to a possibility of inhibiting light emission of the light-emitting layer (light-transmitting material). So the electron transport level of the electron-transport metal oxide nanoparticles contained in the light-transmitting layer is made higher than that of the light-emitting layer (light-emitting material). This causes the electron-transport metal oxide nanoparticles to flow electrons, and causes, in the light-emitting layer (light-emitting material), recombination of holes and the electrons that have fallen to a level of the light-emitting layer (light-emitting material) while moving in the light-emitting layer. As a result, efficient light emission can be achieved. That is, since the functions of charge transport and light emission can be separated in the light-emitting layer, an organic EL element achieving highly efficient, low-voltage driving can be produced.

The light-emitting layer preferably contains a polymer light-emitting material, and more preferably is made of a polymer light-emitting material. A polymer material can be made into a uniform film easily. Further, a polymer material has high affinity with metal oxide nanoparticles, and is suitable to have metal oxide nanoparticles appropriately dispersed therein. Accordingly, this embodiment is particularly preferable as an embodiment in which the light-emitting layer contains metal oxide nanoparticles.

The nanoparticle layer in the present invention is preferably formed by spraying. A nanoparticle layer is usually formed on the upper layer side (the opposite side of the substrate) than the light-emitting layer. At this time, if an organic layer such as the light-emitting layer is formed by a wet process, the light-emitting material used is usually soluble in an organic solvent. Accordingly, for example, if a solution prepared by dispersing metal oxide nanoparticles in an organic solvent is dropped onto the light-emitting layer by a method such as spin coating or an ink jet process, the solution and the light-emitting layer may possibly be mixed and unable to forma stacked structure and the uniformity of the surface may be greatly spoiled. To avoid this, spray coating is employed to form a stacked film. Spraying is a method of forming a film by spraying a solution in a micro mist state. Therefore, the solvent is almost evaporated when the mist is applied onto the substrate, and a nanoparticle layer gets hardly mixed with the light-emitting layer when formed on the light-emitting layer. For this reason, a high-performance organic EL element having a stacked structure with secured functionality can be produced. The same organic solvent as that used in formation of an organic layer such as the light-emitting layer can be used in formation of the nanoparticle layer.

As above, the organic EL element of the present invention is particularly preferable when an organic layer such as the light-emitting layer is formed by a wet process, namely by coating. That is, the light-emitting layer is preferably formed by a wet process, and a layer adjacent to the nanoparticle layer on the anode side in the organic electroluminescent element is preferably formed by a wet process. Those embodiments are particularly preferable as an embodiment in which the nanoparticle layer is formed by spraying.

A device to employ the organic EL element of the present invention is not specifically limited, and the organic EL element of the present invention can be suitably used for various devices, particularly display devices and lightings.

### EFFECT OF THE INVENTION

The organic EL element of the present invention can provide excellent electron injection properties, high resistance to external environmental factors, and buffer effects in transparent electrode formation. As a result, high efficiency, a long life, and high luminance at low power, i.e., low power consumption can be achieved.

### BEST MODES FOR CARRYING OUT THE INVENTION

The present invention is described in more detail based on the following embodiments with reference to the drawings. The present invention is not limited to these embodiments. The members with the same reference numerals in the following respective embodiments are formed by the same process unless otherwise explained.

### Embodiment 1

FIG. 1 is a schematic cross-sectional view of an organic EL element of Embodiment 1. The organic EL element of the present embodiment had a structure where an anode 2, a hole transport layer 3, a light-emitting layer 4, a nanoparticle layer 5, and a cathode 6 were stacked on a substrate 1 in the stated order, as illustrated in FIG. 1. In the following, a production method of the organic EL element of the present embodiment is described.

As the substrate 1 in the present embodiment, a substrate having an insulating surface is preferable. Examples of such a substrate include substrates made of an inorganic material such as glass and quartz; substrates made of plastic such as polyethylene terephthalate; substrates made of ceramics such as alumina; substrates formed by coating an insulator such as SiO₂ or an organic insulating material, on a metal substrate such as aluminum or iron; and substrates formed by performing insulation process such as an anode oxidation method, on the surface of a metal substrate.

First, ITO (indium tin oxide) having a thickness of 150 nm was sputtered on the entire surface of the substrate 1, and the sputtered ITO was patterned into a desired shape and a size by photolithography so that the anode 2 was formed. In the present embodiment, the sputtered ITO was patterned to give 2×2 mm pixels.

Examples of a material of the anode 2, other than ITO, include metals with a high work function, such as gold (Au), platinum (Pt), and nickel (Ni); and transparent conductive materials such as IDIXO (indium oxide-indium zinc oxide; In₂O₃(ZnO)ₙ) and SnO₂.

Next, the produced stack was washed after ITO patterning. Examples of the cleaning include a method of performing ultraviolet rays (UV) ozone cleaning for 30 minutes after performing ultrasonic cleaning for 10 minutes with acetone, isopropyl alcohol (IPA), or the like.

Next, the hole transport layer 3 was formed. The hole transport material (material of the hole transport layer 3) used in the present embodiment was PEDOT-PSSP (EDOT/PSS {poly(ethylene-dioxythiophene)/poly(styrenesulfonate)}). First, a coating liquid for hole transport layer formation containing the above hole transport material was applied on the surface of the anode 2 by a spin coater to provide a film with a thickness of 60 nm. Then, the substrate 1 with an electrode was heat-dried at 200° C. for 5 minutes in high-purity nitrogen atmosphere, so that the solvent (namely, water) in the coating liquid for hole transport layer formation was removed. Thereby, the hole transport layer 3 was formed.

As above, the hole transport layer 3 in the present embodiment can be formed by a wet process, with use of a coating liquid for hole transport layer formation in which at least one kind of hole transport material is dissolved in a solvent. The coating liquid for hole transport layer formation may contain two or more kinds of hole injection transport materials. The coating liquid for hole transport layer formation may contain resin for binding, and may contain, in addition to the resin, a leveling agent, additives (such as a donor and an acceptor), and the like. Examples of the resin for binding include polycarbonate and polyester. The solvent used for the coating liquid for hole transport layer formation is not specifically limited as long as being able to have a hole transport material dissolved or dispersed therein. Examples of the solvent include pure water, methanol, ethanol, THF, chloroform, xylene, and trimethyl benzene. Alternatively, the hole transport layer 3 in the present embodiment may be formed by a dry process. The hole transport layer 3 formed by a dry process also may contain additives (such as a donor and an acceptor) and the like.

The hole transport material may alternatively be a known hole transport material for organic EL elements and organic photoconductors. Examples of the known hole transport material include inorganic p-type semiconductor materials; low-molecular materials including porphyrin compounds, aromatic tertiary amine compounds such as N,N′-bis-(3-methylphenyl)-N,N′-bis-(phenyl)-benzidine (TPD) and N,N′-di(naphthalene-1-yl)-N,N′-diphenyl-benzidine (NPD), hydrazone compounds, quinacridone compounds, and styrylamine compounds; polymer materials such as polyaniline (PANI), 3,4-polyethylenedioxythiophene/polystyrene sulfonate (PEDOT/PSS), poly[triphenylamine derivative] (Poly-TPD), and polyvinylcarbazole (PVCz); and polymer material precursors such as poly(p-phenylenevinylene) precursors (Pre-PPV) and poly(p-naphthalene vinylene) precursors (Pre-PNV).

Thereafter, the light-emitting layer 4 (thickness: 80 nm, for example) in the present embodiment was produced by the following method. First, a coating liquid for light-emitting layer formation was produced by dissolving a polymer light-emitting material in xylene. Next, the coating liquid for light-emitting layer formation was applied on the surface of the hole transport layer 3, with a spin coater. Then, the coating liquid for light-emitting layer formation was heat-dried in high-purity nitrogen atmosphere, so that the solvent in the coating liquid was removed. Thereby, the light-emitting layer 4 was formed.

More specifically, the light-emitting layer 4 was formed by heat-drying the coating liquid prepared by dissolving a fluorene green emission material A in xylene, at a baking temperature of 150° C. The fluorene green emission material A is a copolymer compound of a fluorene ring having alkyl chains R and R′, and at least one unit Ar (Ar′) of an aromatic aryl compound, and the chemical formula thereof is represented by the following formula (A). The fluorene green emission material A has a molecular weight of hundreds of thousands, and has a glass transition point that differs according to the unit to be copolymerized.

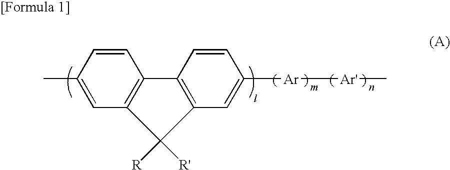

In the above formula (A) , each of R and R′ represents an alkyl chain; each of Ar and Ar′ represents a unit of an aromatic aryl compound; each of l and m is an integer of 1 or greater; and n is an integer of 0 or 1 or greater. Examples of the aromatic aryl compound include dimethylbenzene, pyridine, benzene, anthracene, spirobifluorene, carbazole unit, benzo amine, bipyridine, and benzothiadiazole.

In addition to the above light-emitting materials, known light-emitting materials for organic EL elements can also be used. The light-emitting material is not specifically limited to those examples. Specifically, low-molecular light-emitting materials, polymer light-emitting materials, precursors of polymer light-emitting materials, and the like can be used, and among these, as described above, polymer light-emitting materials are preferable. The light-emitting layer 4 is preferably formed by a wet process. However, in the case that the light-emitting layer 4 is formed by a wet process, a solvent not dissolving the hole transport material is preferably used.

Examples of the low-molecular light-emitting material include aromatic dimethylidene compounds such as 4,4′-bis(2,2′-diphenylvinyl)-biphenyl (DPVBi); oxadiazole compounds such as 5-methyl-2-[2-[4-(5-methyl-2-benzoxazolyl)phenyl]vinyl]benzooxazol; triazole derivatives such as 3-(4-biphenylyl)-4-phenyl-5-t-buthylphenyl-1,2,4-triazole (TAZ); styryl benzene compounds such as 1,4-bis(2-methyl styryl)benzene; fluorescent organic materials such as thiopyrazine dioxide derivatives, benzoquinone derivatives, naphthoquinone derivatives, anthraquinone derivatives, diphenoquinone derivatives, and fluorenone derivatives; and fluorescent organic metallic compounds such as azomethine zinc complexes and (8-hydroxyquinolinato)aluminium complexes (Alq3).

Examples of the polymer light-emitting material include fluorescent organic metallic compounds such as poly(2-decyloxy-1,4-phenylene) (DO-PPP), poly[2,5-bis-[2-(N,N,N-triethyl ammonium)ethoxy]-1,4-phenyl-alto-1,4-phenylene]dibromide (PPP-NEt3+), poly[2-(2′-ethylhexyloxy)-5-methoxy-1,4-phenylenevinylene] (MEH-PPV), poly[5-methoxy-(2-propanoxysulfonide)-1,4-phenylenevinylene] (MPS-PPV), poly[2,5-bis-(hexyloxy)-1,4-phenylene-(1-cyano vinylene)] (CN-PPV), and poly(9,9-dioctylfluorene) (PDAF).

Examples of the precursors of polymer light-emitting materials include PPV precursors, PNV precursors, and PPP precursors.

Next, a material produced by dispersing barium titanate nanoparticles as the metal oxide nanoparticles (electron transport material) into a xylene solution was applied on the light-emitting layer 4 by spraying, so that the nanoparticle layer 5 was formed. More specifically, a coating liquid was first prepared by dissolving the barium titanate nanoparticles in a mixed solvent of xylene-anisole (1:1) to give a concentration of 7 mg/ml. Then, the coating liquid was applied on the light-emitting layer 4 under the following condition: an N₂ flow of 10 l/min; a solution flow of 0.2 l/min; a spray nozzle-moving speed of 2 mm/sec; and a nozzle height of 130 cm. Thereby, the nanoparticle layer 5 having a thickness of 80 nm was formed. The average particle diameter of the nanoparticles was 10 nm. The transmissivity of the nanoparticle layer 5 was 90%.

Nonlimiting examples of the material of the metal oxide nanoparticles, other than the materials described above, include titanium oxides (e.g., TiO₂), cerium oxides (e. g. CeO₂), yttrium oxides (e.g., Y₂O₃), and gallium oxide (Ga₂O₃). Also, materials of the metal oxide nanoparticles apparently having hole transportability, such as ITO, copper oxides (e.g., Cu₂O), molybdenum oxides (e.g., MoO₂(3)), and zinc oxides (e.g., ZnO₂), may have electron transportability depending on the production method and the state of the material, and may be appropriately used according to need. Particularly, alkaline-earth metals, such as barium (Ba) cerium (Ce), and yttrium (Y), and tertiary group elements have high electron injection properties, and thus are preferable as the material of the metal oxide nanoparticles. Among these, barium titanate is particularly preferable. Note that the formation method of the metal oxide nanoparticles is not specifically limited and a known method can be employed. Here, a method leaving a deficiency in the metal oxide nanoparticles is preferable. The number of the kinds of the metal oxide nanoparticles contained in the nanoparticle layer 5 is not specifically limited, and may be appropriately set.

As described below, it appeared that ohmic electron injection occurred in the interface between the nanoparticle layer 5 and the light-emitting layer 4. For this reason, the nanoparticle layer 5 can have a large thickness compared with a conventional electron injection layer, and more specifically, can have a thickness as large as about 50 to 1000 nm (more preferably, 500 to 1000 nm). Increasing the thickness of the nanoparticle layer 5 to this extent makes it possible to effectively suppress the top and bottom leakage, i.e., leakage between the anode and the cathode, which allows improvement in the element yield rate and improvement in the stability and reliability of the element.

The average particle diameter of the metal oxide nanoparticles is not specifically limited as long as being of the order of nanometers. The average particle diameter is preferably smaller than visible light (not larger than 400 nm) in terms of transparency, is more preferably about 5 to 50 nm, and is still more preferably not larger than about 20 nm in terms of easy thickness control, i.e., improvement in thickness uniformity. Further, nanoparticles usually aggregate to form secondary particles being aggregates. The particle diameter in this case, i.e., the particle diameter of each secondary particle is preferably smaller than the wave range (usually 400 to 700 nm) of visible light, and this can improve the transmissivity of the nanoparticle layer 5. The particle diameter of a nanoparticle can be measured by a method such as a BET measuring method.

As described above, the metal oxide nanoparticles preferably contain an imperfect oxide (metal deficiency), have internal charge, form charge transfer complexes with the adjacent layer, and have an electron transport level higher than that of the light-emitting layer 4.

The electron transport level of the nanoparticle layer 5 and the light-emitting layer 4 may be measured by the following method. That is, first, ionization potential is measured using a device such as the work function measuring apparatus AC-3 produced by Riken Keiki Co., Ltd., and this is taken as a valence band level. Meanwhile, a diffuse reflection UV-Vis spectrum is measured using a device such as a UV-Vis-NIR spectroscope (UbestV-570 produced by JASCO Corporation) to calculate a band gap from the absorption edge of an absorption spectrum, and then a conduction band level (electron transport level) is calculated based on the level of the above ionization potential. In, the present embodiment, the nanoparticle layer 5 had an electron transport level of about 4 eV, and the light-emitting layer 4 had an electron transport level of about 2.5 to 3.5 eV which varied according to the light-emitting material.

Next, an aluminum (Al) film was stacked on the nanoparticle layer 5 by vacuum deposition to give a thickness of 300 nm, and thereby the cathode 6 was formed. Note that the thickness of the Al film may be acceptable as long as being in the range of 100 to 500 nm.

Examples of the material of the cathode 6 other than the above material include silver (Ag), gold (Au), and molybdenum (Mo). As above, a material with no high activity can be used as the material of the cathode 6. One criterion for selecting the material of the cathode 6 is a work function, for example; more specifically, a metal with a work function of not less than 4 eV can be selected as the material of the cathode 6.

Lastly, sealing glass (not illustrated) was attached by UV curable resin to the substrate 1, whereby the organic EL element of the present embodiment was completed. The thus-produced organic EL element of the present embodiment is referred to as an element A.

For comparison, an organic EL element without an electron transport material, i.e., an organic EL element without the nanoparticle layer 5 was produced. The thus-produced organic EL element of a comparative embodiment is referred to as an element B.

Also, a coating-type organic EL element having the conventional element structure as illustrated in FIG. 11 was produced. In the following, the production method of the conventional coating-type organic EL element is described.

The substrate 1, the anode 2, the hole transport layer 3, and the light-emitting layer 4 were produced in the same way as that for the element A. Then, the substrate 1 having the light-emitting layer 4 formed thereon was fixed in a metal deposition chamber, and barium (Ba) was deposited on the surface of the light-emitting layer 4 (to give a thickness of for example 5 nm) by vacuum deposition. Subsequently, thereon, aluminum (Al) was deposited by vacuum deposition (to give a thickness of for example 300 nm). Thereby, a cathode 5 was formed.

Examples of the material of the cathode 5 other than the above material include metal electrodes formed by stacking a metal with a low work function and a stable metal, such as Ca/Al, Ce/Al, Cs/Al, or Ca/Al; metal electrodes containing a metal with a low work function, such as Ca—Al alloys, Mg—Ag alloys, and Li—Al alloys; and electrodes formed by combining an insulating layer (thin film) and a metal electrode, such as LiF/Al, LiF/Ca/Al, and BaF₂/Ba/Al.

Lastly, sealing glass (not illustrated) was attached by UV curable resin to the substrate 1, whereby a conventional coating-type organic EL element was completed. The thus-produced conventional coating-type organic EL element is referred to as an element C.

Here, description is given to the properties of the organic EL element A of the present embodiment, and the properties of the elements B and C which were produced for comparison.

The element B of the comparative embodiment had low electron injection properties, and hardly emitted light. In contrast, the element A of the present embodiment, having the cathode 5 produced from Al in the same way efficiently emitted light. This shows that electron injection occurred efficiently and an active metal such as Ba was unnecessary.

FIG. 2 are graphs illustrating the characteristics of the element A of Embodiment 1 and the conventional element C: FIG. 2(a) shows IV characteristics; and FIG. 2 (b) shows current efficiency. As illustrated in FIG. 2(a), the element A, in comparison with the element C, had improved IV characteristics and had a driving voltage decreased by 1.2 V on average. This is apparently because the effect of the nanoparticle layer 5 caused the electron injection properties to be improved. The element A also had improved efficiency compared with the element C, as illustrated in FIG. 2(b). The efficiency was improved particularly on the low current side. This shows that the conventional element C had low electron injection properties on the low current side and thus had a low light-emitting rate whereas, in the present embodiment, electron injection by the nanoparticle layer 5 occurred efficiently on the low current side, i.e., the low voltage side.

In further analyzation, it appeared that electron injection occurred almost ohmically in the interface between the nanoparticle layer 5 and the light-emitting layer 4. This is considered to be due to formation of some matter such as a charge transport complex in the interface between the nanoparticle layer 5 and the light-emitting layer 4.

Whether or not the electron injection occurs ohmically can be determined for example by the following method. FIG. 3 is a conceptual diagram for explaining current mode measurement. FIG. 4 are graphs illustrating the measurement results of a current mode of an organic EL element: FIG. 4(a) shows the result of a common organic EL element; and FIG. 4(b) shows the result of an element according to the organic EL element of Embodiment 1.

First, a stepwise electric field is applied to the organic EL element to measure the current response. More specifically, for example, as illustrated in FIG. 3, an operation of continuously applying a certain voltage for 5 seconds and measuring the current at the time of application every 0.5 seconds is carried out with different voltages in turn. As a result, in the electric field where current is not injected, the current mode is a capacity current mode (dielectric-relaxation phenomenon mode) accompanying a dielectric relaxation phenomenon in the film, as in the region (A) in FIG. 3. In contrast, when current is injected and current flows in the bulk, the current mode changes to a current mode following the electric field, i.e., an ohmic current mode (ohmic mode), as in the region (B) in FIG. 3. Accordingly, in a common organic EL element in which electron injection occurred in application of a certain voltage, a voltage of not higher than threshold voltage led to the capacity current mode, and a voltage of not lower than threshold voltage led to an ohmic response to change the current mode to the ohmic mode, as illustrated in FIG. 4(a). That is, only voltage of not less than certain threshold voltage enables current to be injected into the bulk. Meanwhile, the element illustrated in FIG. 4(b) was in the ohmic mode from the start, which means that the current flowed without a threshold. In the element A of the present embodiment in which the metal oxide nanoparticles were used as an electron transport layer, the current mode was in the mode as illustrated in FIG. 4(b) because the internal charge naturally contained in the nanoparticles can be sent into the light-emitting layer 4.

Further, the metal oxide nanoparticles used for the element A apparently lacked Ba. For this reason, the metal oxide nanoparticles are in the state where electron accumulation occurs easily, which is considered as the core of electron injection.

Further, in comparison with the element C, the element A did not contain an active metal such as Ba as the material of the cathode 6, and therefore can suppress degradation of the cathode 6 due to external factors, migration, and the like, thereby extending the life.

### Embodiment 2

FIG. 5 is a cross-sectional view of an organic EL element of Embodiment 2. The organic EL element of the present embodiment had a structure where the anode 2, the hole transport layer 3, the light-emitting layer 4, a nanoparticle-containing film 7, and the cathode 6 were stacked on the substrate 1 in the stated order, as illustrated in FIG. 5. As above, the only difference between the present embodiment and Embodiment 1 is that, instead of the nanoparticle layer 5, the nanoparticle-containing film 7 formed by dispersing the metal oxide nanoparticles in resin (polymer support) was used as the electron transport layer.

The nanoparticle-containing film 7 was formed by applying a solution, prepared by dissolving and/or dispersing in xylene a mixture of barium titanate and polystyrene as a binder resin giving a weight ratio of 3:1 (polystyrene: barium titanate=3:1), on the light-emitting layer 4 by spraying. The thickness of the nanoparticle-containing film 7 was 200 nm, and the transmissivity of the nanoparticle-containing film 7 at this time was 90%.

As the binder resin, polyimide, polycarbonate, an acrylic resin, and an inert resin can be used as well as polystyrene. Further, electron-transport material may be blended into resin.

FIG. 6 are measurement results of the nanoparticle-containing film in the organic EL element of Embodiment 2 by AFM: FIG. 6(a) is a plan view; and FIG. 6(b) is a perspective view. As illustrated in FIG. 6, the nanoparticle-containing film 7 had aggregates of the metal oxide nanoparticles, each with a size in a plan direction of about 1 to 5 micrometers and with a size in a depth direction of about 50 nm.

An element D of the present embodiment was produced by vapor-depositing aluminum (Al) on the nanoparticle-containing film 7 and then sealing the element, as in Embodiment 1. This element D showed IVL characteristics almost the same as those of the element A. As with the element A, the element D of the present embodiment also can extend the life, compared with the conventional element C.

### Embodiment 3

FIG. 7 is a cross-sectional view of an organic EL element of Embodiment 3. The organic EL element of the present embodiment had a structure where the anode 2, the hole transport layer 3, the light-emitting layer 4, the nanoparticle-containing film 7, and a transparent cathode 8 made of a transparent conductive film were stacked on the substrate 1 in the stated order, as illustrated in FIG. 7. As above, although the present embodiment had the same structure as that of Embodiment 2, the material of the cathode was different. That is, the cathode 8 in Embodiment 3 was formed by sputtering ITO. The cathode 8 had a thickness of 100 nm. Here, the thickness of the cathode 8 may be about 50 to 150 nm.

The material of the cathode 8 in the present embodiment may be a transparent conductive material such as indium zinc oxide (IZO) IDIXO, and SnO₂, or the like, as well as ITO.

For comparison, an element was produced which was the same as the element C except that Al had a thickness of 5 nm and was semi-transparent, and thereon ITO was sputtered. In this element, the light-emitting layer 4 was damaged by ITO sputtering, and showed only 30% of the initial efficiency compared with the element C. In contrast, the characteristics of the element of the present embodiment and the element A were broadly similar to each other. That is, in the conventional element, the light-emitting layer is damaged by oxygen, secondary electrons, or the like in the ITO sputtering on the light-emitting layer. This can be apparently prevented by inserting a layer containing nanoparticles between the light-emitting layer and the cathode as in the element of the present embodiment because the layer containing nanoparticles functions as a buffer layer to protect the light-emitting layer from being damaged in the ITO film formation.

The element of the present embodiment can also be suitably used as an organic EL element having the top emission structure, a transparent organic EL element in which the whole element is transparent, or the like.

The transmissivity of the cathode 8 in the present embodiment is not specifically limited as long as it is in the range enabling the organic EL element to emit light from the cathode 8 side. The transmissivity is preferably not less than 80% (more preferably not less than 90%). A transmissivity of less than 80% may decrease the luminance by 20% or more. When the luminance decreases, an element life gets short by a percentage of about a square of the decreased amount of the luminance. Consequently, a decrease in the luminance by 20% or more may lead to a notable decrease in the element life by 40% or more. The transmissivity can be measured with a visible light spectrometer.

### Embodiment 4

FIG. 8 is a cross-sectional view of an organic EL element of Embodiment 4. The organic EL element of the present embodiment had a structure where the anode 2, the hole transport layer 3, the light-emitting layer 4, a hole blocking layer 9, the nanoparticle-containing film 7, and the cathode 6 were stacked on the substrate 1 in the stated order, as illustrated in FIG. 8. As above, the only difference between the present embodiment and Embodiment 2 is that the hole blocking layer 9 was sandwiched between the light-emitting layer 4 and the nanoparticle-containing film 7.

The hole blocking layer 9 was formed by applying a xylene solution having a carbon nanotube dispersed in polycarbonate, by spraying. The thickness of the hole blocking layer 9 may be about 10 to 50 nm.

The hole blocking layer 9 may be made of a hole blocking compound (compound having hole blocking properties) alone, or may be, according to need, made of a polymer compound in which a hole blocking compound is dispersed. A hole blocking compound having electron transport properties and having an ionization potential higher than that of the light-emitting layer 4 is preferable as the hole blocking compound used in the present embodiment. However, the material used for the hole blocking layer 9 and the material used for the nanoparticle-containing film 7 need to be different. Further, the hole blocking layer 9 preferably has LUMO lower than LUMO of the light-emitting layer 4, and preferably has HOMO falling in around the middle of HOMO of the light-emitting layer 4 and HOMO of the nanoparticle layer 5.

Examples of the material of the hole blocking layer 9 (hole blocking compound), other than the above materials, include oxadiazole compounds such as 2-(4′-tert-buthylphenyl)-5-(4″-biphenyl)-1,3,4-oxadiazole; diphenoquinone compounds such as 3,5,3′,5′-tetrakis-tert-butyl diphenoquinone; quinolinic acid complex compounds such as tris (8-hydroxy-quinolino) aluminum (III) and bis (8-hydroxy-quinolino) beryllium; benzoxazole compounds such as zinc-bis-benzoxazole; benzothiazole compounds such as zinc-bis-benzothiazole; triazole compounds such as tris (1,3-diphenyl-1,3-propanediono) (monophenanthroline) europium (III) and 1-phenyl-2-biphenyl-5-para-tert-buthylphenyl-1,3,4-triazole; 2, polyquinone polymers; polypyridine polymers; fullerene; and carbon nanotubes.

The element having the hole blocking layer 9 can improve the efficiency, compared with the element A. This is because the holes leaked from the light-emitting layer 4 are blocked by the hole blocking layer 9 and thus are able to be used in light emission.

### Embodiment 5

FIG. 9 is a cross-sectional view of an organic EL element of Embodiment 5. The organic EL element of the present embodiment had a structure where the anode 2, the hole transport layer 3, the light-emitting layer 4 containing metal oxide nanoparticles, the nanoparticle-containing film 7, and the cathode 6 were stacked on the substrate 1 in the stated order, as illustrated in FIG. 9. As above, the only difference between the present embodiment and Embodiment 2 is that the metal oxide nanoparticles were dispersed in the light-emitting layer 4. The thus-produced organic EL element of the present embodiment is referred to as an element E.

The material of the metal oxide nanoparticles dispersed in the light-emitting layer 4 was barium titanate, and the weight percentage of these metal oxide nanoparticles to the light-emitting material in the light-emitting layer 4 was controlled to be 25%. The average particle diameter of these metal oxide nanoparticles was 20 nm.

FIG. 10 are graphs illustrating the characteristics of the element E of Embodiment 5 and the conventional element C: FIG. 10(a) shows IV characteristics; and FIG. 10(b) shows current efficiency. As illustrated in FIG. 10(a), the element E, in comparison with the element C, had improved IV characteristics and had a driving voltage decreased by 2 V on average. This is apparently because the effect of the nanoparticle layer 5 caused the electron injection properties to be improved. The element E also had improved efficiency compared with the element C, as illustrated in FIG. 10(b). The efficiency was improved particularly on the low current side. This shows that the conventional element C had low electron injection properties on the low current side and thus had a low light-emitting rate whereas, in the present embodiment, electron injection by the nanoparticle layer 5 occurred efficiently on the low current side, i.e., the low voltage side.

The electron injection occurred more efficiently apparently because the same kind of the metal oxide nanoparticles were blended in the nanoparticle-containing film 7 and the light-emitting layer 4. Further, the element E provided high efficiency compared with the element A apparently because the metal oxide nanoparticles performed the electron transportation in the light-emitting layer 4. Since the metal oxide nanoparticles perform the electron transportation in the light-emitting layer 4, deterioration of the light-emitting layer 4 caused by the electrons in the conventional element C can be suppressed. Hence, the life can be extended compared with the element A.

The present application claims priority to Patent Application No. 2007-340310 filed in Japan on Dec. 28, 2007 under the Paris Convention and provisions of national law in a designated State, the entire contents of which are hereby incorporated by reference.

### BRIEF DESCRIPTION OF DRAWINGS

FIG. 1 is a cross-sectional view of the organic EL element of Embodiment 1.

FIG. 2 are graphs illustrating the characteristics of the element A of Embodiment 1 and the conventional element C: FIG. 2(a) shows IV characteristics; and FIG. 2(b) shows current efficiency.

FIG. 3 is a conceptual diagram for explaining current mode measurement.

FIG. 4 are graphs illustrating the measurement results of a current mode of an organic EL element: FIG. 4(a) shows the result of a common organic EL element; and FIG. 4(b) shows the result of an element according to the organic EL element of Embodiment 1.

FIG. 5 is a cross-sectional view of an organic EL element of Embodiment 2.

FIG. 6 are measurement results of the nanoparticle-containing film in the organic EL element of Embodiment 2 by AFM: FIG. 6(a) is a plan view; and FIG. 6(b) is a perspective view.

FIG. 7 is a cross-sectional view of the organic EL element of Embodiment 3.

FIG. 8 is a cross-sectional view of the organic EL element of Embodiment 4.

FIG. 9 is a cross-sectional view of the organic EL element of Embodiment 5.

FIG. 10 are graphs illustrating the characteristics of the element E of Embodiment 5 and the conventional element C: FIG. 10(a) shows IV characteristics; and FIG. 10(b) shows current efficiency.

FIG. 11 is a cross-sectional view schematically illustrating a conventional coating-type organic EL element.

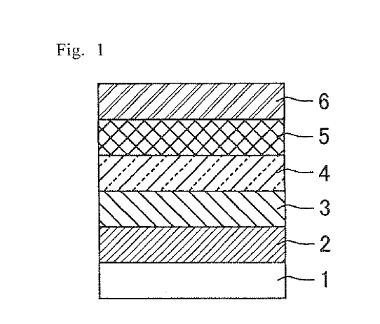

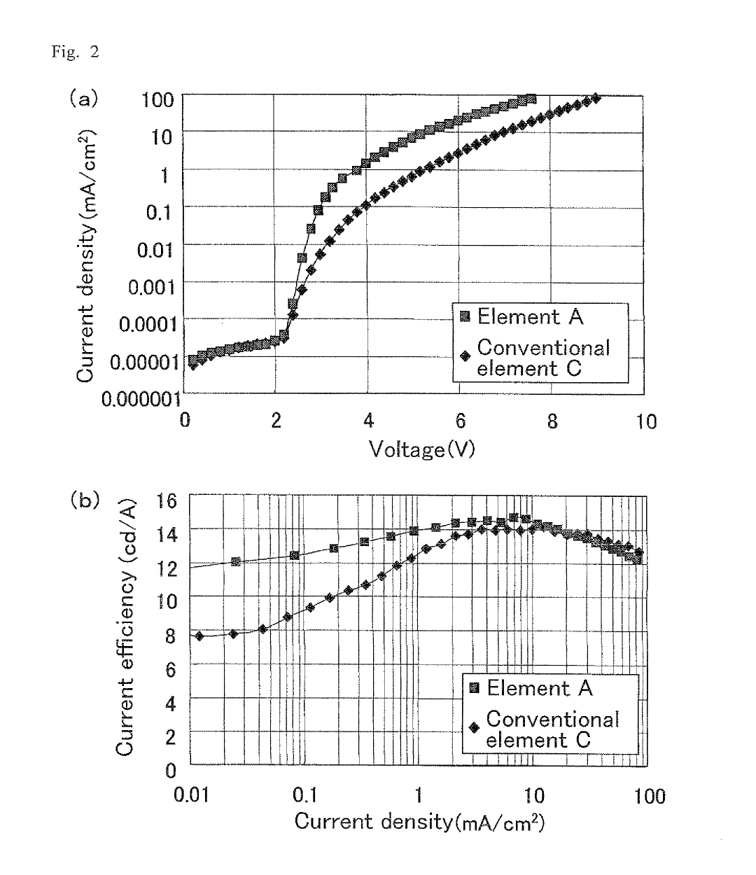

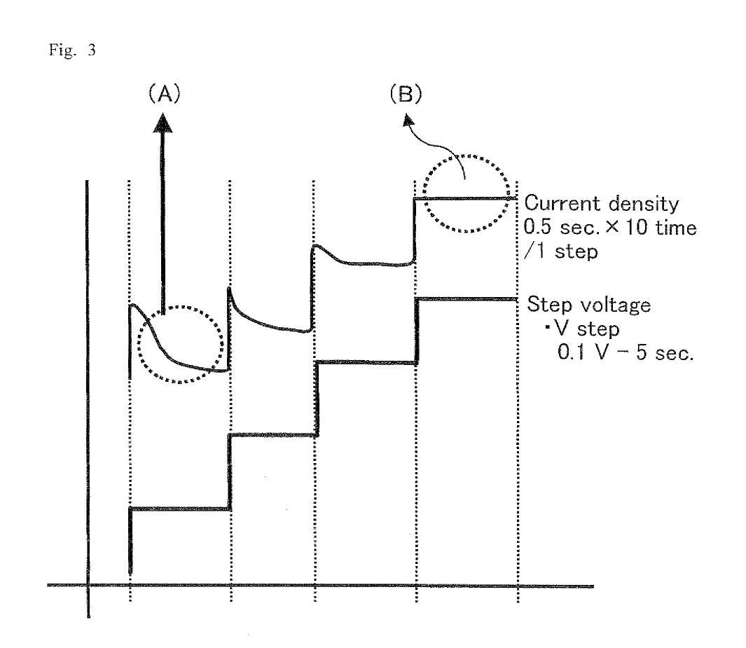

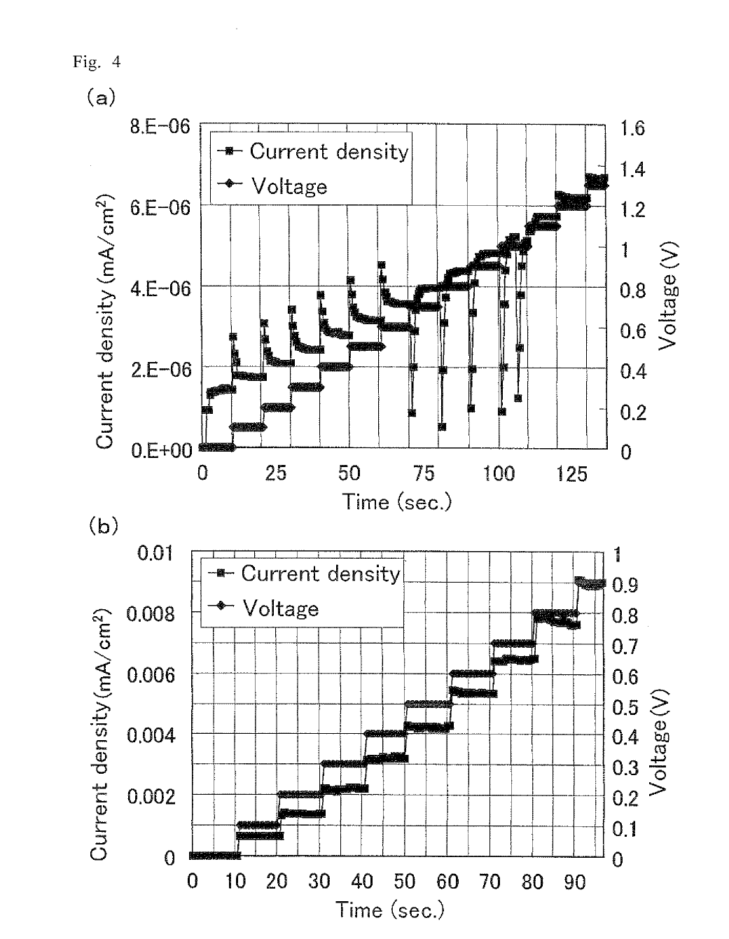

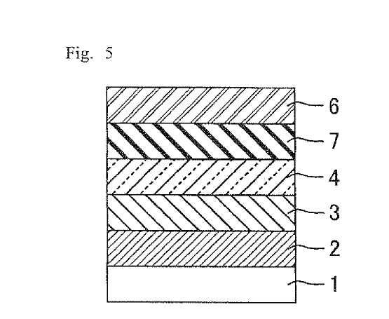

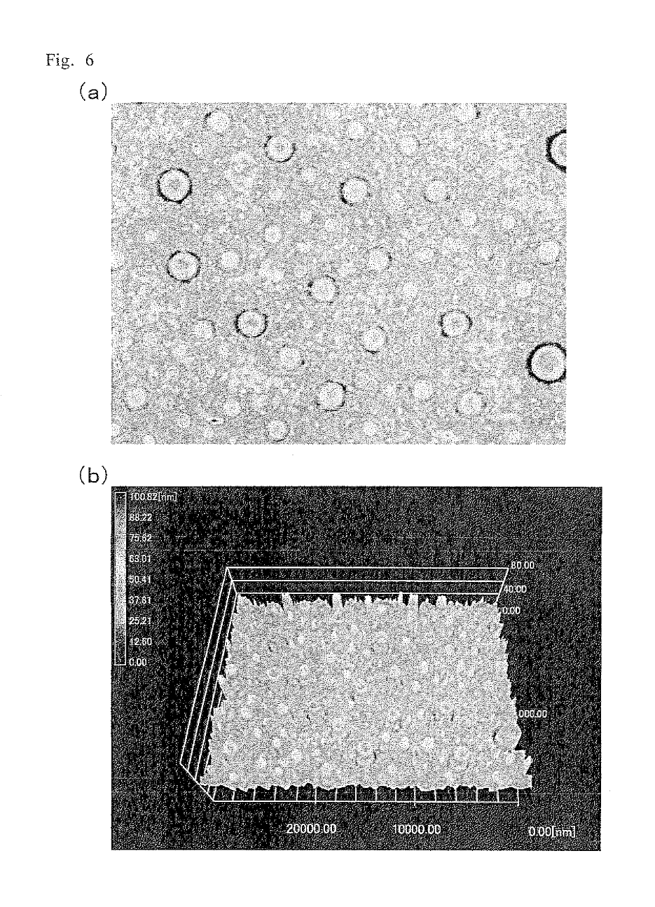

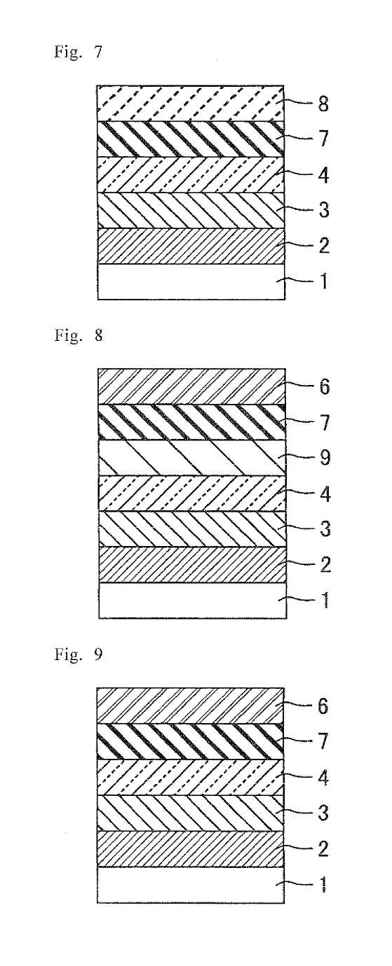

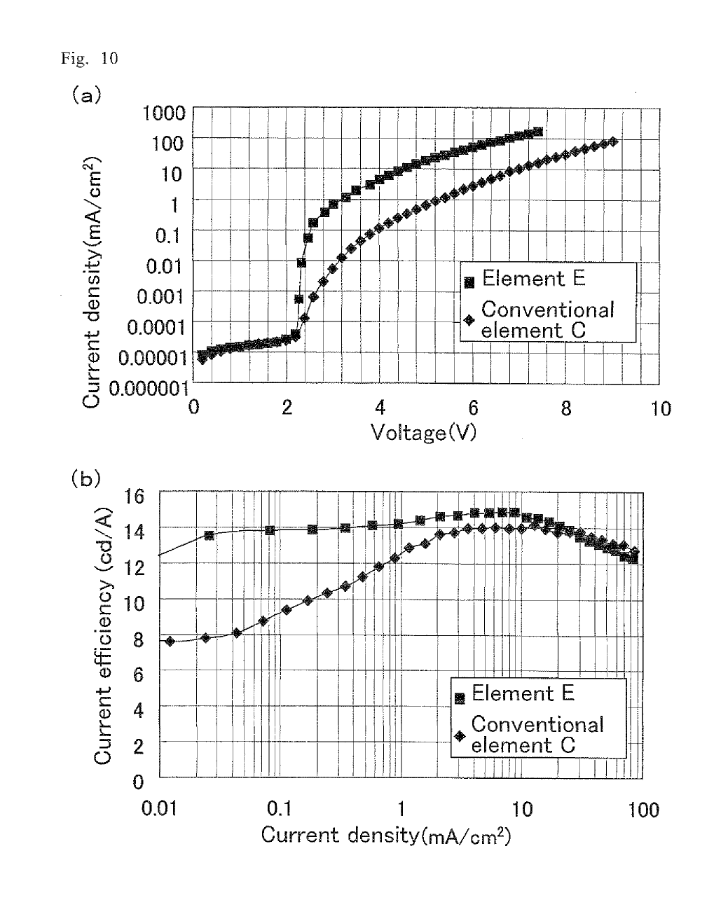

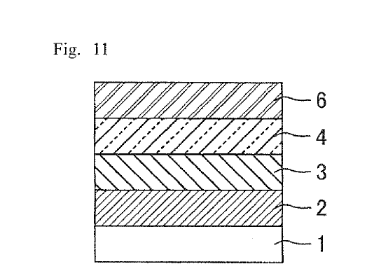

### EXPLANATION OF NUMERALS AND SYMBOLS

1: Substrate
2: Anode
3: hole transport layer
4: Light-emitting layer
5: Nanoparticle layer
6, 8: Cathode
7: Nanoparticle-containing film
9: Hole blocking layer

1. An organic electroluminescent element having an anode, a cathode, and a light-emitting layer sandwiched between the anode and the cathode, the organic electroluminescent element comprising:
a nanoparticle layer containing metal oxide nanoparticles, between the light-emitting layer and the cathode.

2. The organic electroluminescent element according to claim 1,
wherein the nanoparticle layer is made of the metal oxide nanoparticles.

3. The organic electroluminescent element according to claim 1,
wherein the nanoparticle layer contains the metal oxide nanoparticles and a polymer support.

4. The organic electroluminescent element according to claim 3,
wherein the nanoparticle layer contains cluster aggregates of the metal oxide nanoparticles.

5. The organic electroluminescent element according to claim 1,
wherein the metal oxide nanoparticles have an electron transport level higher than the electron transport level of the light-emitting layer.

6. The organic electroluminescent element according to claim 1,
wherein the cathode contains an inert metal.

7. The organic electroluminescent element according to claim 1,
wherein the cathode is formed by sputtering.

8. The organic electroluminescent element according to claim 1,
wherein the cathode is transparent.

9. The organic electroluminescent element according to claim 1,
wherein the organic electroluminescent element has a hole blocking layer between the light-emitting layer and the nanoparticle layer.

10. The organic electroluminescent element according to claim 1,
wherein the light-emitting layer contains metal oxide nanoparticles.

11. The organic electroluminescent element according to claim 10,
wherein the metal oxide nanoparticles contained in the light-emitting layer include the same kind of particles as the metal oxide nanoparticles contained in the nanoparticle layer.

12. The organic electroluminescent element according to claim 10,
wherein the metal oxide nanoparticles contained in the light-emitting layer have an electron transport level higher than the electron transport level of the light-emitting layer.

13. The organic electroluminescent element according to claim 1,
wherein the light-emitting layer contains a polymer light-emitting material.

14. The organic electroluminescent element according to claim 1,
wherein the nanoparticle layer is formed by spraying.

15. The organic electroluminescent element according to claim 1,
wherein the light-emitting layer is formed by a wet process.

16. The organic electroluminescent element according to claim 1,
wherein a layer adjacent to the nanoparticle layer on the anode side in the organic electroluminescent element is formed by a wet process.
